(19) United States
(12) Patent Application Publication
(10) Pub. No.: US 2002/0000830 A1
(43) Pub. Date: Jan. 3, 2002

(54) Noise-resistant output stage circuit

(75) Inventor: Jin-Cheng Huang, Taipei Hsien (TW)

Correspondence Address: DARBY & DARBY P.C., 805 Third Avenue, New York, NY, 10022, US

(73) Assignee: Via Technologies, Inc.

(21) Appl. No.: 09/862,558

(22) Filed: May 22, 2001

(30) Foreign Application Priority Data
May 24, 2000 (TW) 89110008

(51) Int. Cl. H03K 19/003

(52) U.S. Cl. 326/27

(57) ABSTRACT

A noise-resistant output stage circuit with inverse-feedback control comprising two NMOS transistors. A first NMOS transistor is coupled to a first high voltage via the drain, and coupled to a first input signal via the gate. A second MOS transistor is coupled to a source of the first MOS transistor via the drain, and performing an output terminal of the output stage circuit, therewith the gate of the second MOS transistor receiving a second input signal; an alternative of the first input signal or the second input signal presents a second high voltage and the other presents a grounding, wherein the second high voltage exceeds the first high voltage. Preferably, the second high voltage is greater than twice the first high voltage. In operation, an alternative of the first NMOS transistor or the second NMOS transistor operates within a linear region.

### CROSS REFERENCE TO RELATED APPLICATION

The reader's attention is directed to U.S. Pat. No. 6,011,409 and U.S. Pat. No. 6,133,757, which is incorporated herein by reference.

### BACKGROUND OF THE INVENTION

1. Field of the Invention

The present invention relates to an output stage circuit, and particularly to a low voltage output stage circuit with anti-noise capability. It is suitable for applying the present invention to various electronic systems that are provided with low-voltage output, and with output signals of satisfactory qualities, thereby possible errors at receiving terminals are substantially decreased.

2. Description of Related Art

Nowadays, high speed electrical systems are increasingly desirable, therefore enhancements of data transmitting speed between individual circuits are necessary. Because the data transmission applying small-amplitude signals has the advantages of high speed and less noise, the system interfaces at present mostly have the specifications that include small-amplitude signals. For example, in the 100 Mbit/sec/pin GTL+ bus, signals are switched between 0.6 V(level L) and 1.5 V(level H); in the 266 Mbit/sec/pin 1.5 V Fourfold Fast AGP bus, signals are switched between 0 V(level L) and 1.5 V(level H); in the 200 Mbit/sec/pin S2K (0D) bus, signals are switched between 0.3 V(level L) and 1.6 V(level H); in the specification of the 800 Mbit/sec/pin RAM bus, signals are switched between 1.0 V(level L) and 1.8 V(level H); in the 200 Mbit/sec/pin S2K bus, signals are switched between 0 V(level L) and 1.6 V(level H).

Although the data transmission applying small-amplitude signals provides the advantages of high speed and less noise for a system, meanwhile, a problem follows that the noise margin of the system gets narrowed. During the data transmission, the narrowing of the noise margin might result in the receiving error of the system due to the noises generated within.

FIG. 1 shows a schematic diagram illustrating a manner in which data is transmitted via a bus between general high-speed integrated circuits. Since neither terminal resistors nor serial resistors are additionally coupled to the bus, the layout for the bus on a PCB becomes very simple and resistors of a considerable quantity could be saved. This kind of bus is now in widespread use.

Refer to FIG. 1. The transmission line 10 is respectively coupled to the integrated circuits 20 and 30 at both ends. The integrated circuit 20 includes an output buffer 22 that sends out logic signals and an input buffer 24 that receives logic signals. The integrated circuit 30 includes an output buffer 32 that sends out logic signals and an input buffer 34 that receives logic signals. After the integrated circuit 20 sends out a signal via the output buffer 22, the integrated circuit 30 receives this signal via the input buffer 34. Conversely, after the integrated circuit 30 sends out a signal via the output buffer 32, the integrated circuit 20 receives this signal via the input buffer 24. Because receiving terminals are of high impedance, the reflection coefficient is consequently 1 (i.e., the amplitude of the back wave is equal to that of the incident wave). Consequently, the impedance matching between the turned-on impedence for the output buffer at the transmitting end and the characteristic impedance (indicated by Zo) of the transmission line 10 becomes very important.

FIG. 2 shows the circuit chart of an output stage in a general integrated circuit. As shown in FIG. 2, the output stage circuit includes a NMOS transistor M1 and a PMOS transistor M2 that is serially connected between a high voltage VPP and a grounding GND. The gates of the transistors receive output signals Vg1 and Vg1, i.e., 0 V or VPP, respectively. When Vg1=VPP and Vg2=VPP, NMOS transistor M1 presents ON-state and PMOS transistor M2 is in OFF-state, whereby the node Vio outputs 0 V stably. On the other hand, when Vg1=0 V and Vg2=0 V, PMOS transistor M2 presents ON-state and NMOS transistor M1 presents OFF-state, whereby the node Vio outputs Vpp stably.

According to the analysis, in a conventional output stage, the output signals of different logic levels will bring about the ON-state of a specific transistor. To ascertain that if the turn-on resistance of the ON-state and the characteristic impedance of the transmission line are matching for each other, therefore, the characteristic IV curves of different transistors in the output stage are to be considered. Respectively, FIG. 3 and FIG. 4 illustrate the characteristic IV curve and the current-voltage chart of the loading line of NMOS transistor M1 and PMOS transistor M2 of the output stage shown in FIG. 2.

In FIG. 3, the symbol 40 indicates a characteristic IV curve of the NMOS transistor M1, and the symbol 42 indicates a loading line of the NMOS transistor M1. Generally, the characteristic IV curve of a MOS transistor could be divided into a linear region and a saturation region. According to FIG. 3, the characteristic IV curve 40 of the NMOS transistor M1 intersects with the loading line 42 at an intersection 43 in the saturation region of the characteristic IV curve of the NMOS transistor M1. The current in the saturation region is formulated with the following equations:

$${I}_{D1} = \frac{1}{2} \cdot {μ}_{n} \cdot {C}_{ox} \cdot N1 \cdot ( \frac{{W}_{1}}{{L}_{1}} ) \cdot {( {V}_{gs1} - {V}_{tn} )}^{2}$$

That is,

$${I}_{D1} = \frac{1}{2} \cdot {μ}_{n} \cdot {C}_{ox} \cdot N1 \cdot ( \frac{{W}_{1}}{{L}_{1}} ) \cdot {( VPP - {V}_{tn} )}^{2} \qquad ( 1 )$$

Wherein, μₙ indicates the electron mobility, Cₒₓ indicates the capacitance per unit area of the element's gate oxide layer, N1 indicates the number of transistor M1, W₁/L₁ indicates the width-to-length ratio of the element, and Vₜₙ indicates the critical voltage of the element. It should be noted that the channel length modulation effect is not considered in equation (1). According to equation (1), obviously, if the source and gate of the MOS transistor are subjected to the noise variation of V_{gs1} shown as ΔV, the current I_{D1} will vibrate in accordance with ΔV, based on a quadratic relation. Specifically, I_{D1} is proportional to (VPP−Vₜₙ±ΔV)². Accordingly, the less VPP is, the more current I_{D1} is susceptible to the noise.

Similarly, PMOS transistor M2 comprises the same characteristics. In FIG. 4, symbol 45 indicates the characteristic IV curve of the PMOS transistor M2, and symbol 47 indicates the loading line thereof. Similarly, the intersection 48 is positioned in the saturation region of the characteristic IV curve 45. The current in the saturation region is formulated with the following equations:

$${I}_{S2} = \frac{1}{2} \cdot {μ}_{p} \cdot {C}_{ox} \cdot N2 \cdot ( \frac{{W}_{2}}{{L}_{2}} ) \cdot {( {V}_{sg2} - \vert {V}_{tp2} \vert )}^{2} \qquad ( 1 )$$

That is,

$${I}_{S2} = \frac{1}{2} \cdot {μ}_{p} \cdot {C}_{ox} \cdot N2 \cdot ( \frac{{W}_{2}}{{L}_{2}} ) \cdot {( VPP - \vert {V}_{tp2} \vert )}^{2} \qquad ( 2 )$$

Wherein, μₚ indicates the electron mobility,N2 indicates the number of transistor M2, and W₂/L₂ indicates the width-to-length ratio of the element, and Vₜₚ₂ indicates the critical voltage of the element. According to formula (2), it is obvious that the circuit is susceptible to the effects of noise.

### SUMMARY OF THE INVENTION

Accordingly, the object of the present invention is to provide an output stage circuit that obviating the problem above, and provides a reduction in noise-effects thereby the quality of the signal received at a receiving terminal could be optimized.

According to the object above, the present invention provides a noise-resistant output stage circuit comprising two NMOS transistors that are named first NMOS transistor and second MOS transistor. The first NMOS transistor is coupled to a first high voltage (i.e., VPP) via the drain, and is coupled to a first input signal via the gate. The second MOS transistor is coupled to a source of the first MOS transistor via the drain, and presents an output terminal of the output stage circuit, and the gate of the second MOS transistor receives a second input signal. An alternative of the first input signal or the second input signal presents a second high voltage (i.e., VDD) and the other presents a low voltage (e.g. 0 V), wherein the second high voltage exceeds the first high voltage. Preferably, the second high voltage exceeds the double of the first high voltage. By employing the relationship between the characteristic IV curve and a loading line thereof, accordingly, an alternative of the first NMOS transistor or the second NMOS transistor will operate within the linear region. Further more, the potential of the input signal exceeds that of the conventional equivalents, thus the effects of noise is reduced.

### BRIEF DESCRIPTION OF THE DRAWINGS

The following detailed description, given by way of examples and not intended to limit the invention to the embodiments described herein, will best be understood in conjunction with the accompanying drawings, in which:

FIG. 1 illustrates a schematic diagram showing a paradigm of data transmission via bus between typical high-speed integrated circuits.

FIG. 2 illustrates the circuit chart of the output stage in a typical integrated circuit.

FIG. 3 illustrates a characteristic IV curve of the NMOS transistor M1 of the output stage shown in FIG. 2 and a current-voltage chart of the loading line thereof.

FIG. 4 illustrates a characteristic IV curve of the PMOS transistor M2 of the output stage shown in FIG. 2 and a current-voltage chart of the loading line therein.

FIG. 5 illustrates an output stage according to an embodiment of the integrated circuit of the present invention.

FIG. 6 illustrates a characteristic IV curve of the transistor M4 of the output stage shown in FIG. 5 and a current-voltage chart of the loading line thereof.

FIG. 7 illustrates a characteristic IV curve of the transistor M3 of the output stage shown in FIG. 5 and a current-voltage chart of the loading line thereof.

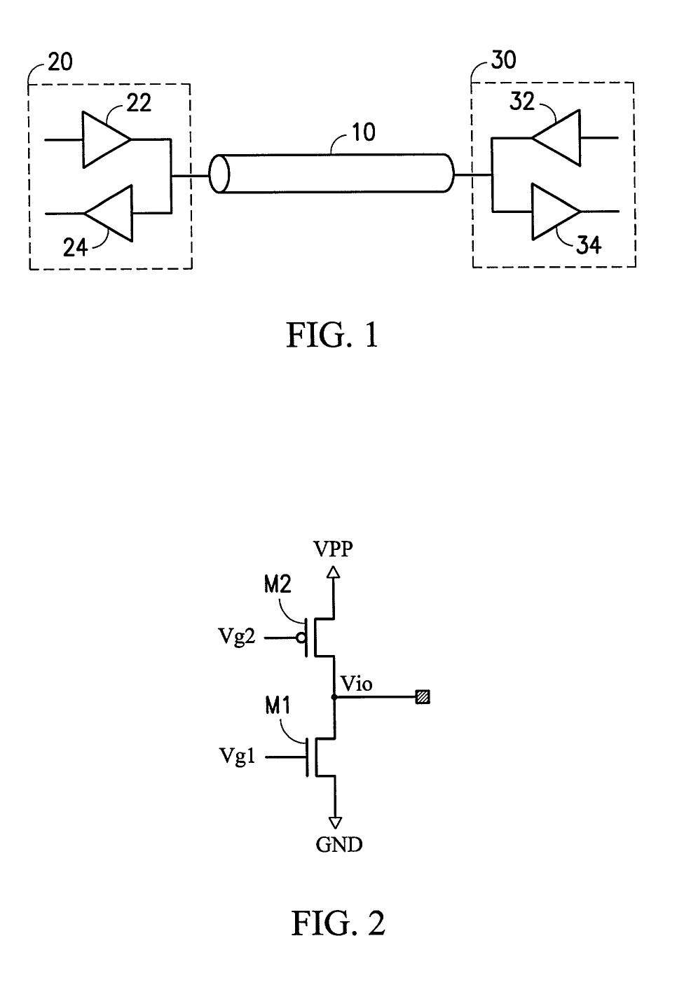

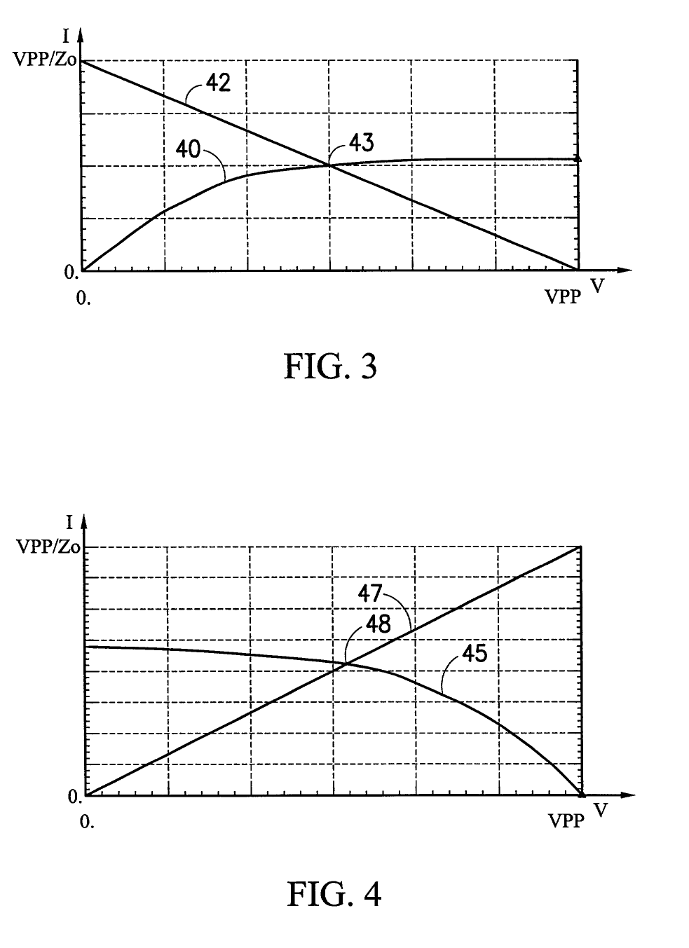

### DESCRIPTION OF THE PREFERRED EMBODIMENT

The present embodiment utilizes transistors within a linear region, by means of varying the intersection (i.e., bias point of the circuit) of a characteristic IV curve of respective transistor and a loading line. An equation for current in the linear region is applied to enhance the amplitude of input signals transmitted toward the output stage, whereby the effects of noise will be reduced.

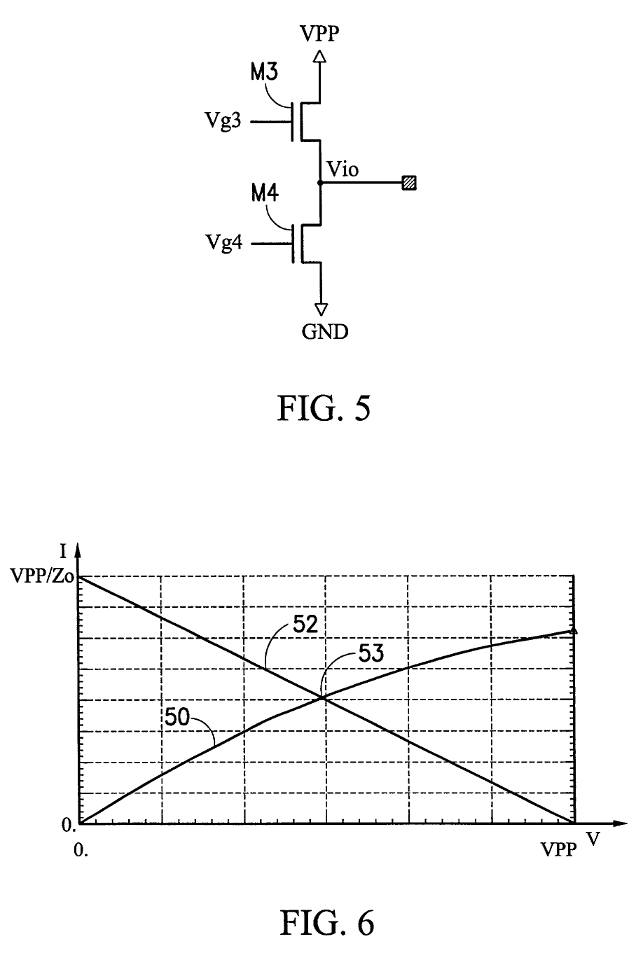

FIG. 5 illustrates an output stage circuit used in an integrated circuit according to an embodiment of the present invention. The output stage circuit includes an NMOS transistor M3 and a NMOS transistor M4 that serially connected between a high voltage VPP and a grounding GND, and the gates of the transistors respectively receive signals Vg3 and Vg4 that switch between high/low logic levels of VDD or 0 V, wherein VDD ≧=2×VPP. When Vg3 is VDD and Vg4 is 0 V, the NMOS transistor M3 presents On-state thereby the node Vio outputs VPP stably; and when Vg3 is 0 V and Vg4 is VDD, the NMOS transistor M4 presents On-state thereby stably the node Vio outputs 0 V.

The output stage circuit shown in FIG. 5 is different from that of prior arts (for example, the circuit shown in FIG. 2) primarily in two aspects. First, a NMOS transistor is applied to replace the conventional PMOS transistor in each output buffer. Second, the high logic levels of the input signals (i.e., Vg3 and Vg4) transmitted to the output stage circuit are raised to VDD. Below, effects of the variations will be illustrated according to the characteristic IV curve of the NMOS transistor M3, the NMOS transistor M4, and the associated loading line.

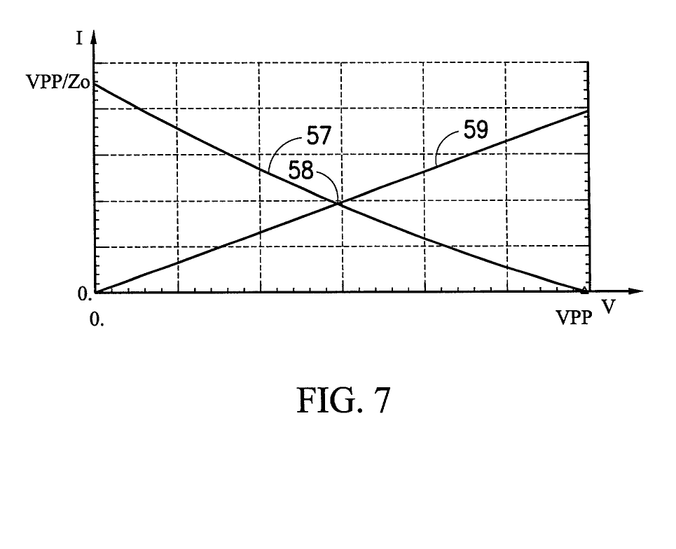

FIG. 6 and FIG. 7 illustrate the characteristic IV curves of NMOS transistor M4 and NMOS transistor M3 in the output stage circuit shown in FIG. 5, and a current voltage figure of the loading line of the output stage circuit, respectively. Initially, in FIG. 6, characteristic IV curve 50 of the transistor M4 intersects with the loading line 52 at an intersection 53 in the linear region of the characteristic IV curve 50 of the transistor M4. The current in the linear region is formulated with the following equations:

$${I}_{D4} = \frac{1}{2} {μ}_{n} {C}_{ox} N4 \cdot ( \frac{{W}_{4}}{{L}_{4}} ) \cdot [ 2 ( {V}_{gs4} - {V}_{tn4} ) - {V}_{ds4} ] \cdot {V}_{ds4}$$

That is,

$$\begin{matrix}{I}_{D4} = \frac{1}{2} {μ}_{n} {C}_{ox} N4 \cdot ( \frac{{W}_{4 }}{{L}_{4}} ) \cdot [ 2 ( VDD - {V}_{tn4} ) - \\ ( VPP - {I}_{D4} \cdot {Z}_{0} ) ] \cdot ( VPP - {I}_{D4} \cdot {Z}_{0} )\end{matrix} \qquad ( 3 )$$

Wherein, N4 indicates the number of the transistor M4, W₄/L₄ indicates the width-to-length ratio of the element, and Vₜₙ₄ indicates the critical voltage of the element.

In formula (3), VDD represents the high logic level of input of the present embodiment (VDD>VPP), and the relation between I_{D4} and the ΔV is linear. Therefore, the variation of I_{D4} in accordance with noise ΔV, the variation of voltage, is significantly decreased, and the object of reduction in noise-effects is achieved.

In FIG. 7, the characteristic IV curve 57 of the transistor M3 intersects with the loading line 59 at an intersection 58 in the linear region of the characteristic IV curve 57 of the transistor M3. The current in the linear region is formulated with the following equations:

$${I}_{D3} = \frac{1}{2} {μ}_{n} {C}_{ox} N3 \cdot ( \frac{{W}_{3}}{{L}_{3}} ) \cdot [ 2 ( {V}_{gs3} - {V}_{tn3} ) - {V}_{ds3} ] \cdot {V}_{ds3}$$

That is,

$$\begin{matrix}{I}_{D3} = \frac{1}{2} {μ}_{n} {C}_{ox} N3 \cdot ( \frac{{W}_{3}}{{L}_{3}} ) \cdot [ 2 ( VDD - {I}_{D3} \cdot {Z}_{0} - {V}_{tn3} ) - \\ ( VPP - {I}_{D3} \cdot {Z}_{0} ) ] ( VPP - {I}_{D3} \cdot {Z}_{0} )\end{matrix} \qquad ( 4 )$$

Wherein, N3 indicates the number of the transistor M3, W₃/L₃ indicates the width-to-length ratio of the element, and Vₜₙ₃ indicates the critical voltage of the element. In the formula (4), due to VDD>VPP, the variation of I_{D3} in accordance with a same noise, ΔV, is significantly decreased, and the object of reduction in noise-effects is achieved.

Accordingly, the output stage circuit of the present embodiment is provided with the characteristic of noise-resistance. Furthermore, in the present embodiment, conventional PMOS transistors are replaced with NMOS transistors, wherein the electron mobility μₙ exceeds the electric-hole mobility μₚ and VDD is greater than VPP, thus the dimensions of transistors could be significantly reduced and the die size is also significantly reduced.

While the invention has been described with reference to a preferred embodiment, the description is not intended to be construed in a limiting sense. It is therefore contemplated that the appended claims will cover any such modifications or embodiments as may fall within the scope of the invention defined by the following claims and their equivalents.

What is claimed is:

1. An output stage circuit with noise-resistant capability, comprising:
a first MOS transistor, coupled to a first high voltage via a drain of the first MOS transistor, for receiving a first input signal via a gate of the first MOS transistor; and
a second MOS transistor of the same type of the first MOS transistor, coupled to a source of the first MOS transistor via a drain of the second MOS transistor, for receiving a second input signal via a gate of the second MOS transistor;
wherein either the first input signal or the second input signal is a second high voltage and the other input signal is a low voltage; the second high voltage exceeds the first high voltage and the drain of the second MOS transistor is an output terminal of the output stage circuit.

2. The output stage circuit of claim 1, wherein the first MOS transistor and the second MOS transistor are both NMOS transistors.

3. The output stage circuit of claim 1, wherein either the first MOS transistor or the second MOS transistor operates within a linear region.

4. The output stage circuit of claim 1, wherein the second high voltage exceeds the double of the first high voltage.

5. An output stage circuit with noise-resistant capability, comprising:
a first MOS transistor, coupled to a first high voltage via a drain of the first MOS transistor and receiving a first input signal via a gate of the first MOS transistor; and
a second MOS transistor, coupled to a source of the first MOS transistor via a drain of the second MOS transistor, for receiving a second input signal via a gate of the second MOS transistor;
wherein either the first input signal or the second input signal is a second high voltage and the other input signal is a low voltage; and the drain of the second MOS transistor is an output terminal of the output stage circuit.

6. The output stage circuit of claim 5, wherein either the first MOS transistor or the second MOS transistor operates within a linear region.

7. The output stage circuit of claim 5, wherein the second high voltage is greater than twice the first high voltage.
